(19) United States
(12) Patent Application Publication
(10) Pub. No.: US 2026/0343917 A1
(43) Pub. Date: Oct. 29, 2026

(54) SEMICONDUCTOR DEVICE STRUCTURE WITH DIELECTRIC NANOSTRUCTURE AND METHOD FOR FORMING THE SAME

(71) Applicant: Taiwan Semiconductor Manufacturing Co., Ltd., Hsinchu (TW)

(72) Inventors: Hong-Chih Chen, Changhua County (TW); Fu-Hsiang Su, Zhubei City (TW); Jin-Aun Ng, Hsinchu (TW); Shih-Hsun Chang, Hsinchu (TW)

(21) Appl. No.: 19/736,267

(22) Filed: Jul. 9, 2026

Related U.S. Application Data
(63) Continuation of application No. 18/817,827, filed on Aug. 28, 2024.
(60) Provisional application No. 63/655,153, filed on Jun. 3, 2024.

(51) Int. Cl. H10D 30/01; H10D 30/43; H10D 30/67; H10D 62/10; H10D 64/01; H10W 10/00; H10W 10/20

(52) U.S. Cl. CPC H10D 30/014; H10D 30/43; H10D 30/6735; H10D 30/6757; H10D 62/121; H10D 64/017; H10D 64/018; H10W 10/021; H10W 10/20

(57) ABSTRACT

A semiconductor device structure is provided. The semiconductor device structure includes a substrate. The semiconductor device structure includes a channel nanostructure and a dielectric nanostructure over the substrate. The dielectric nanostructure is between the substrate and the channel nanostructure. The semiconductor device structure includes a gate cut structure passing through the channel nanostructure and the dielectric nanostructure. The semiconductor device structure includes a first source/drain structure over the substrate and connected to the channel nanostructure. The inner spacer is between the first source/drain structure and the dielectric nanostructure.

### CROSS-REFERENCE FOR RELATED APPLICATION

This application is a continuation of U.S. Patent Application No. 18/817,827, filed Aug. 28, 2024, entitled “Semiconductor Device Structure with Dielectric Nanostructure and Method for Forming the Same,” which claims the benefit of U.S. Provisional Application No. 63/655,153, filed on Jun. 3, 2024, the entirety of which are incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a top view of a semiconductor device structure, in accordance with some embodiments.

FIG. 2A-1 is a cross-sectional view illustrating the semiconductor device structure along a sectional line I-I’ in FIG. 1, in accordance with some embodiments.

FIGS. 2A-1 to 2J-1 are cross-sectional views of various stages of a process for forming a semiconductor device structure, in accordance with some embodiments.

FIG. 2A-2 is a cross-sectional view illustrating the semiconductor device structure along a sectional line II-II’ in FIG. 1, in accordance with some embodiments.

FIGS. 2A-2 to 2J-2 are cross-sectional views of various stages of a process for forming a semiconductor device structure, in accordance with some embodiments.

FIG. 2A-3 is a cross-sectional view illustrating the semiconductor device structure along a sectional line III-III’ in FIG. 1, in accordance with some embodiments.

FIG. 2A-4 is a cross-sectional view illustrating the semiconductor device structure along a sectional line IV-IV’ in FIG. 1, in accordance with some embodiments.

FIG. 2F-3 is a top view of the semiconductor device structure of FIGS. 2F-1 and 2F-2, in accordance with some embodiments.

FIG. 2G-3 is a top view of the semiconductor device structure of FIGS. 2G-1 and 2G-2, in accordance with some embodiments.

FIG. 2G-4 is a cross-sectional view illustrating the semiconductor device structure along a sectional line III-III’ in FIG. 2G-3, in accordance with some embodiments.

FIG. 2I-3 is a top view of the semiconductor device structure of FIGS. 2I-1 and 2I-2, in accordance with some embodiments.

FIG. 2J-3 is a top view of the semiconductor device structure of FIGS. 2J-1 and 2J-2, in accordance with some embodiments.

FIG. 2J-4 is a cross-sectional view illustrating the semiconductor device structure along a sectional line IV-IV’ in FIG. 2J-3, in accordance with some embodiments.

FIG. 2J-5 is a cross-sectional view illustrating the semiconductor device structure along a sectional line V-V’ in FIG. 2J-3, in accordance with some embodiments.

FIG. 2J-6 is a cross-sectional view illustrating the semiconductor device structure along a sectional line IV-IV’ in FIG. 2J-3, in accordance with some embodiments.

FIG. 3 is a cross-sectional view illustrating a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as "substantially parallel" or "substantially perpendicular" may be interpreted as not to exclude insignificant deviation from the specified arrangement and may include for example deviations of up to 10°. The word "substantially" does not exclude "completely" e.g. a composition which is "substantially free" from Y may be completely free from Y.

The term "about" may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term "about" in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain structure(s) may refer to a source or a drain, individually or collectively dependent upon the context.

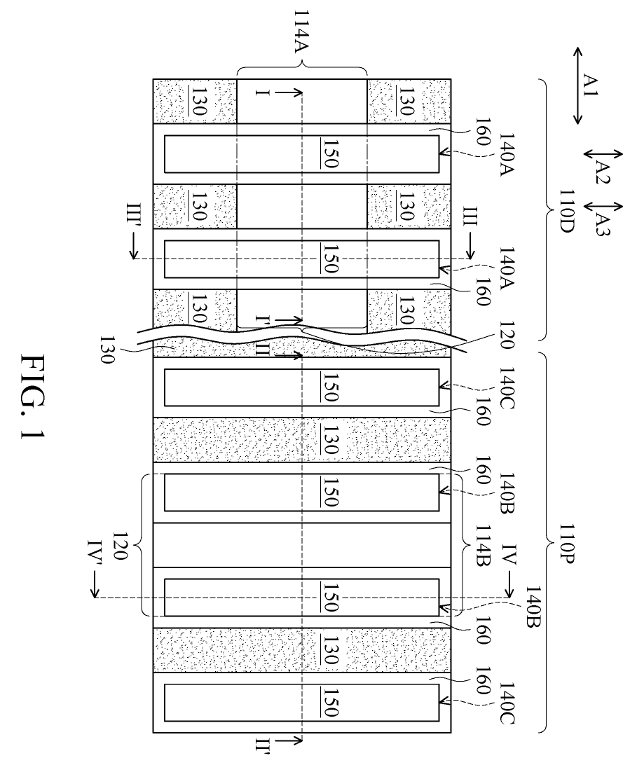

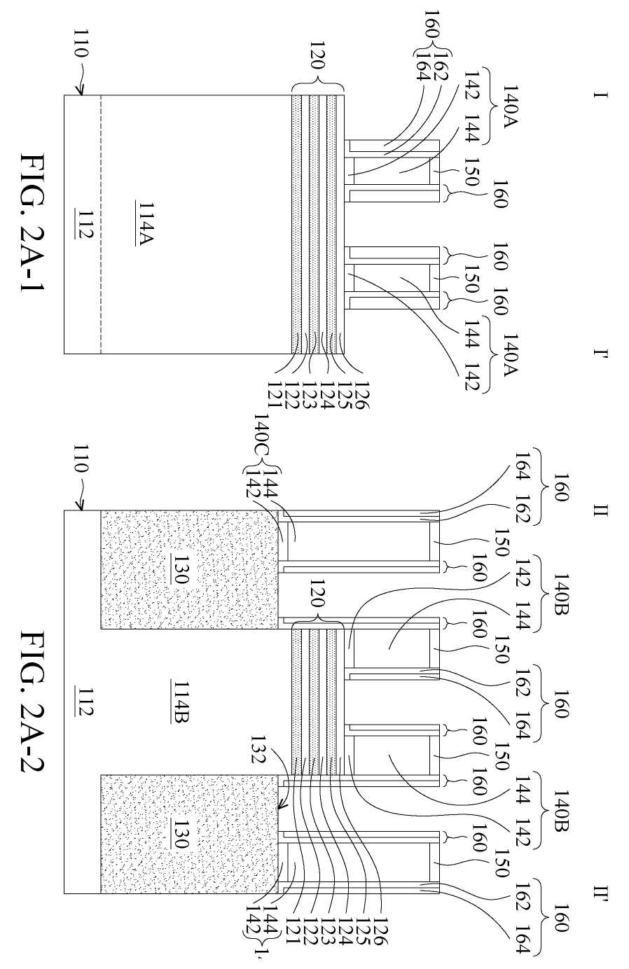

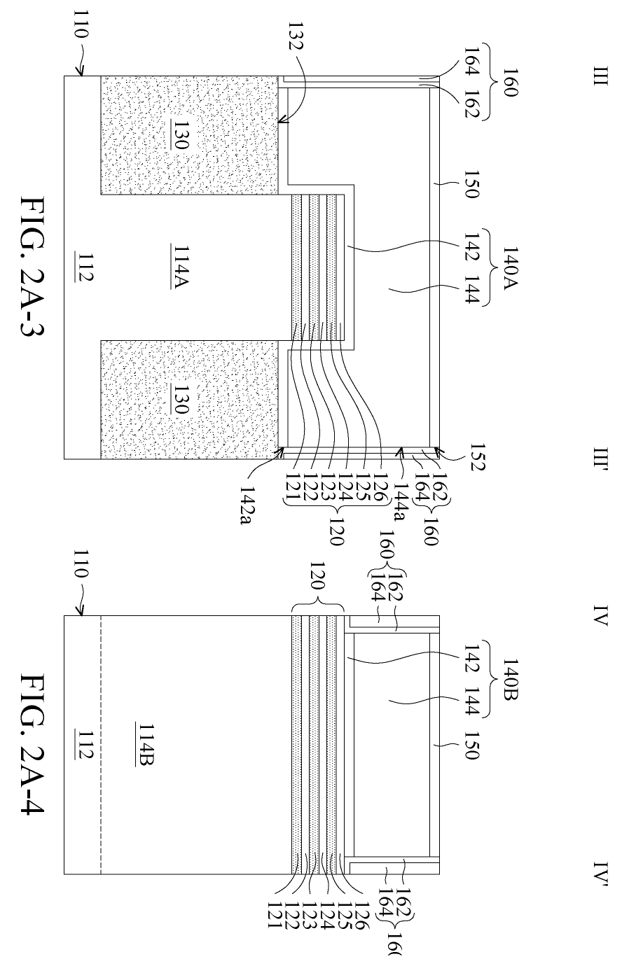

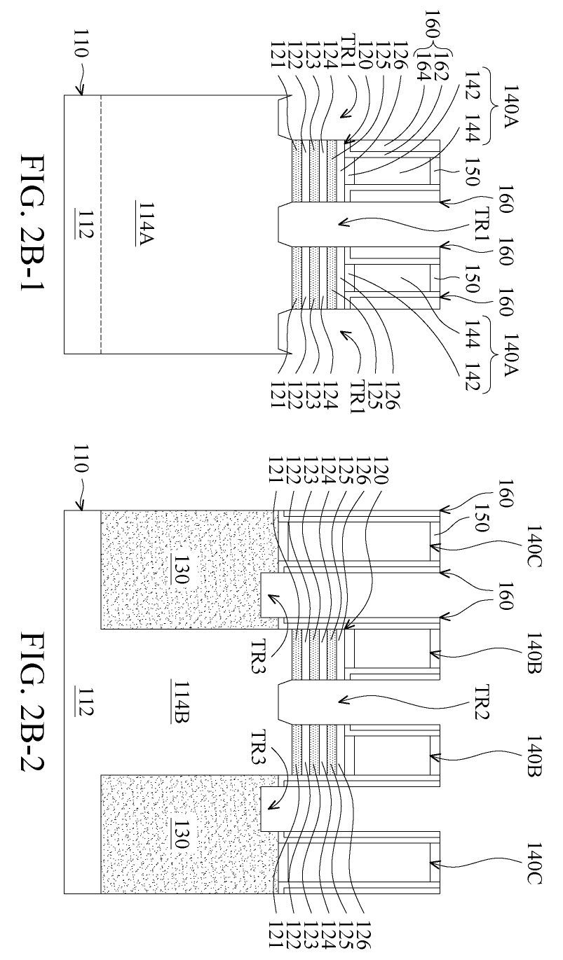

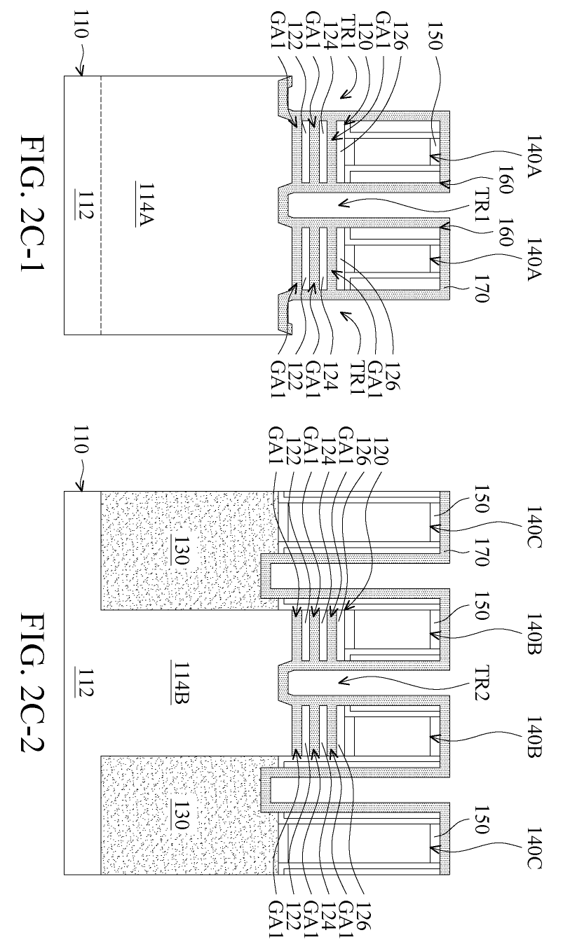

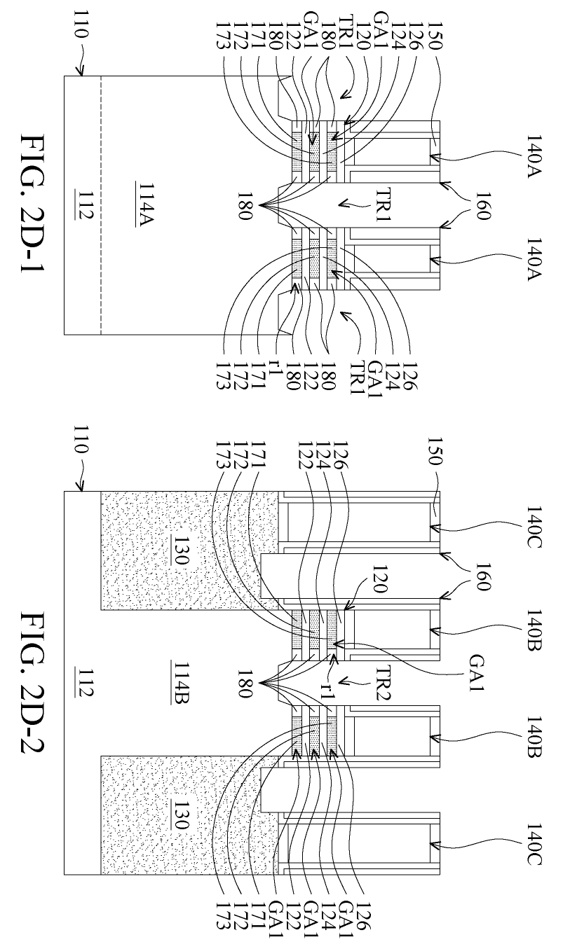

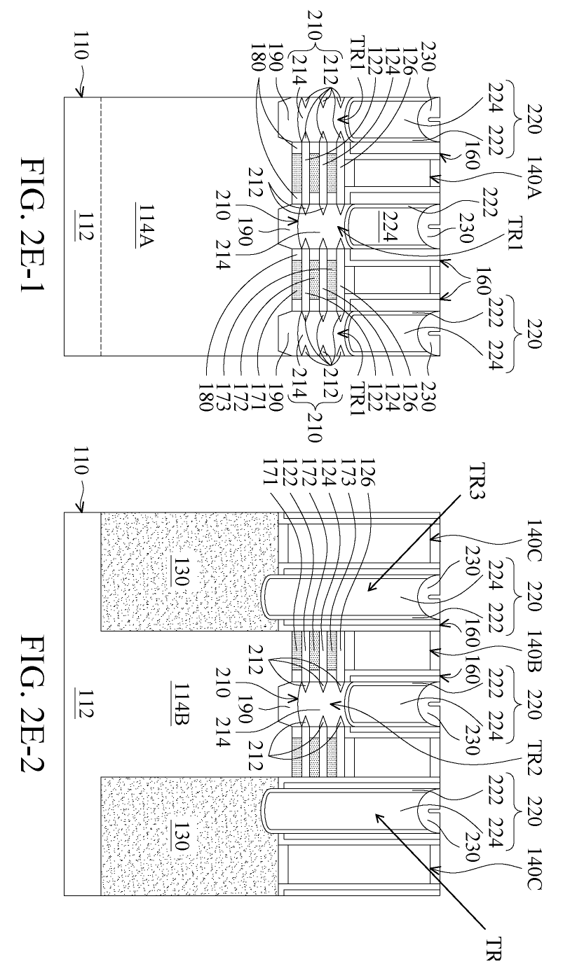

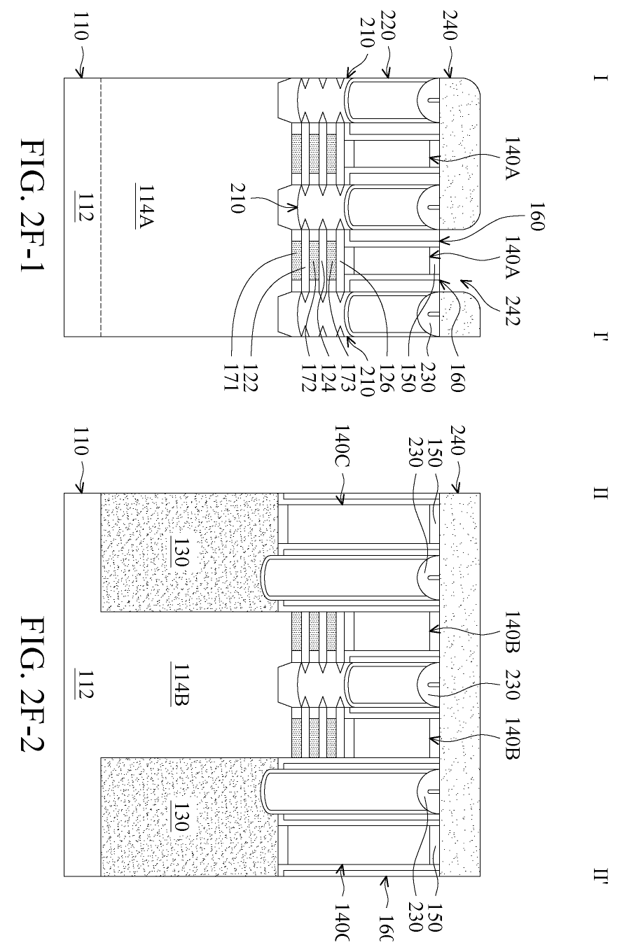

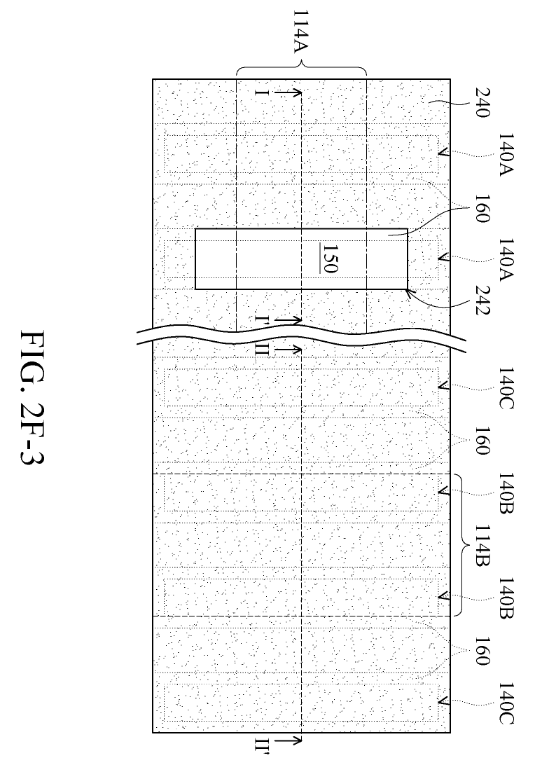

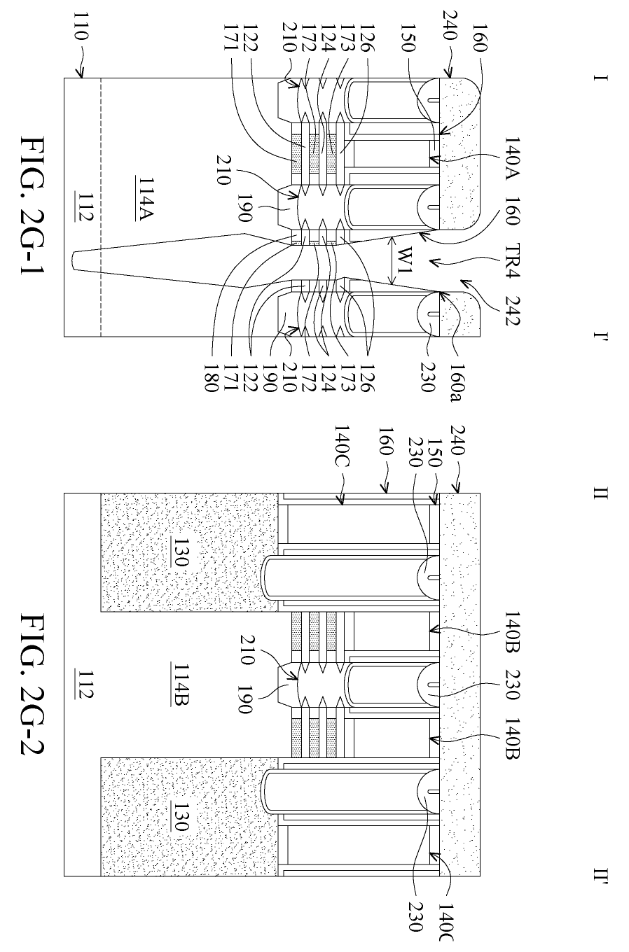

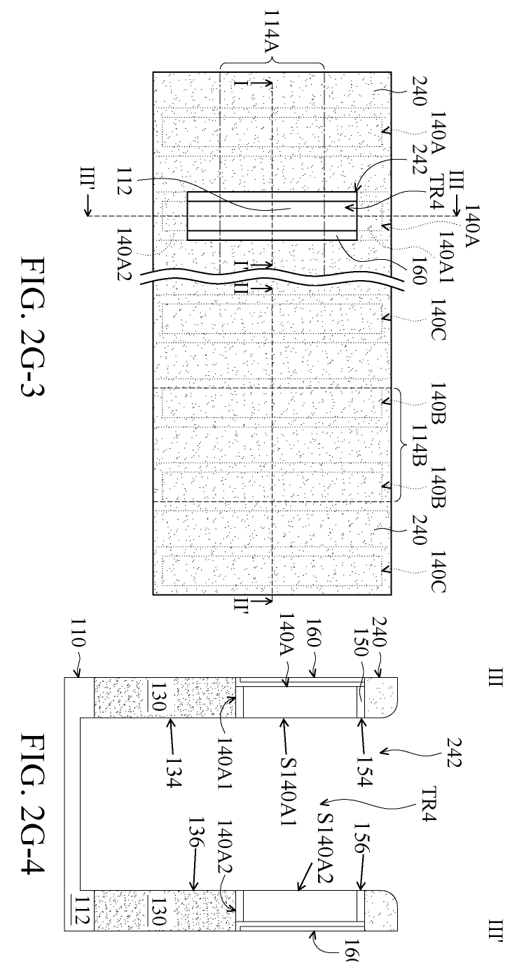

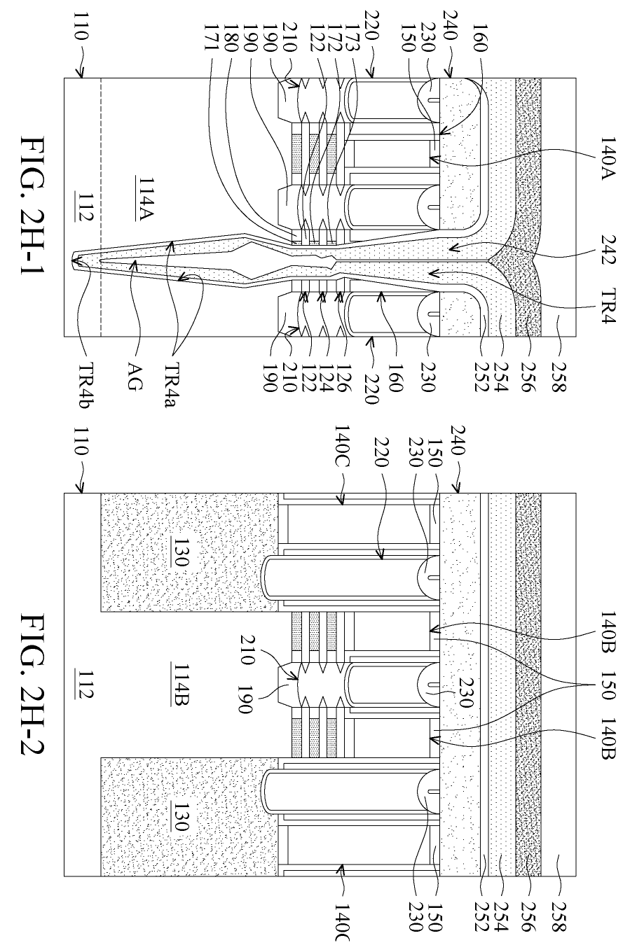

FIG. 1 is a top view of a semiconductor device structure, in accordance with some embodiments. FIG. 2A-1 is a cross-sectional view illustrating the semiconductor device structure along a sectional line I-I’ in FIG. 1, in accordance with some embodiments.

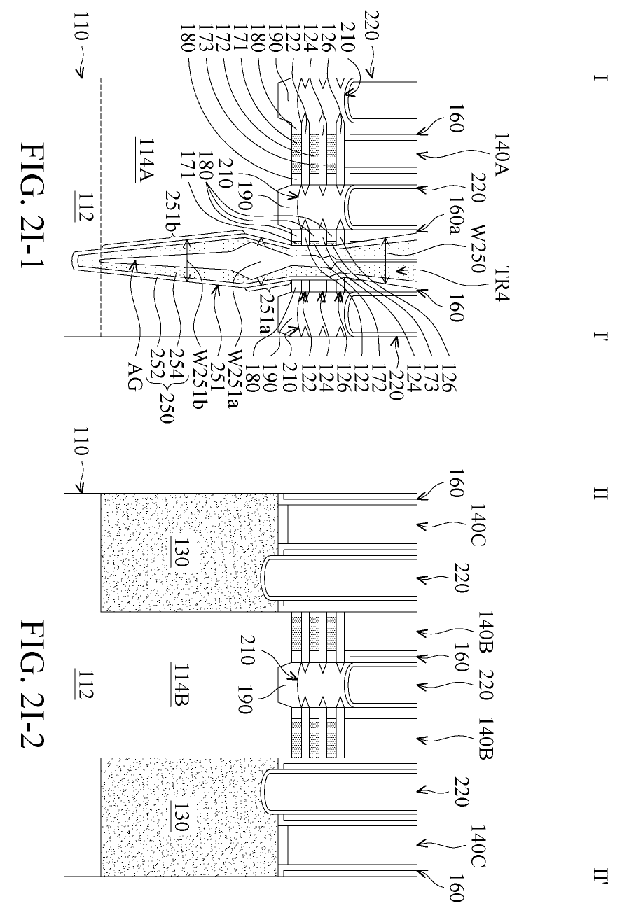

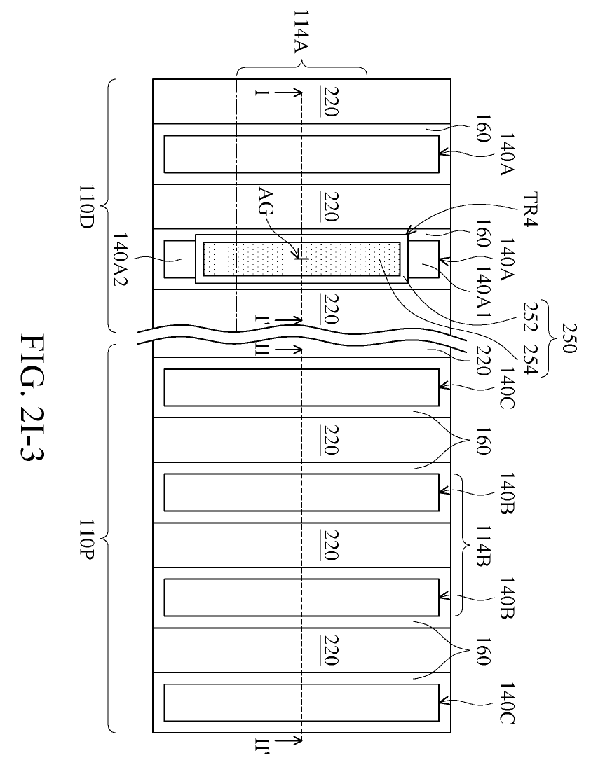

FIG. 2A-2 is a cross-sectional view illustrating the semiconductor device structure along a sectional line II-II’ in FIG. 1, in accordance with some embodiments. FIG. 2A-3 is a cross-sectional view illustrating the semiconductor device structure along a sectional line III-III’ in FIG. 1, in accordance with some embodiments.

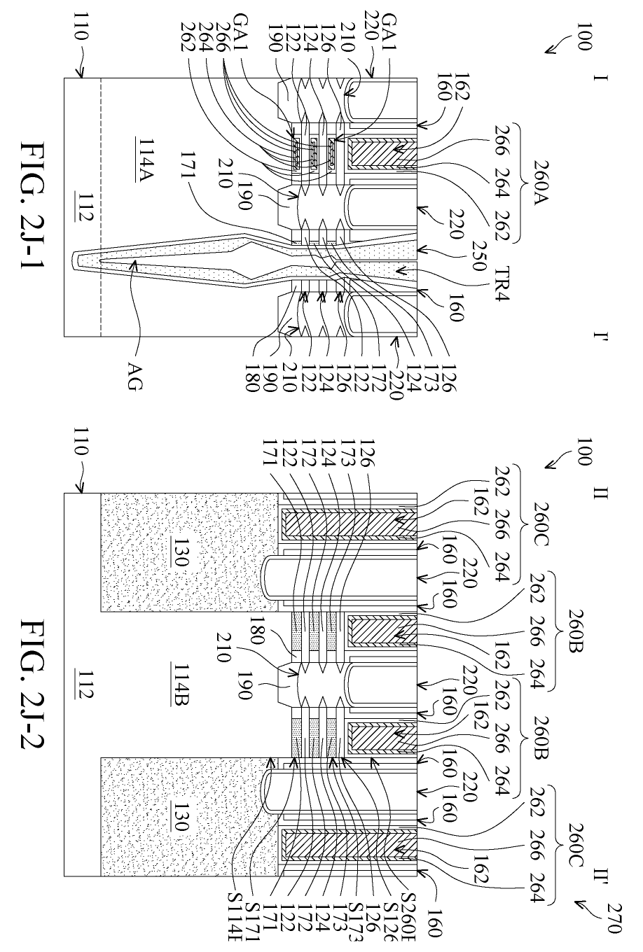

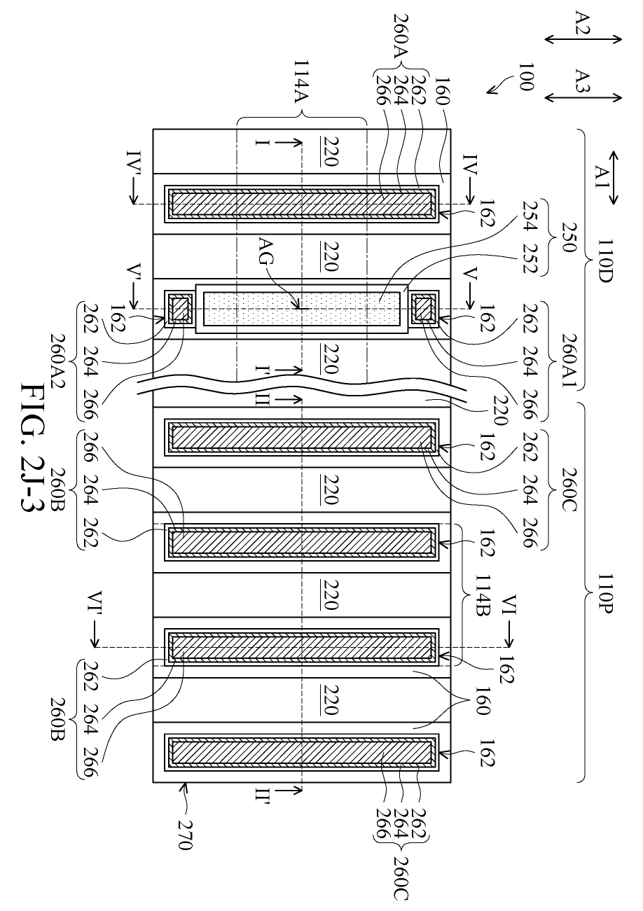

FIG. 2A-4 is a cross-sectional view illustrating the semiconductor device structure along a sectional line IV-IV’ in FIG. 1, in accordance with some embodiments. FIGS. 2A-1 to 2J-1 are cross-sectional views of various stages of a process for forming a semiconductor device structure, in accordance with some embodiments. FIGS. 2A-2 to 2J-2 are cross-sectional views of various stages of a process for forming a semiconductor device structure, in accordance with some embodiments.

As shown in FIGS. 1, 2A-1 and 2A-2 a substrate 110 is provided, in accordance with some embodiments. The substrate 110 has a device region 110D and a peripheral region 110P, in accordance with some embodiments. The device region 110D is used to form devices such as active devices or passive devices, in accordance with some embodiments. The peripheral region 110P is used to form a seal ring structure, in accordance with some embodiments. The seal ring structure is configured to protect the devices in the device region 110D from being attacked by moisture, in accordance with some embodiments.

The substrate 110 has a base 112 and fins 114A and 114B over the base 112, in accordance with some embodiments. The fin 114A has a longitudinal axis A1, in accordance with some embodiments. The fin 114B has a longitudinal axis A2, in accordance with some embodiments. The longitudinal axis A1 is not parallel to the longitudinal axis A2, in accordance with some embodiments. In some embodiments, the longitudinal axis A1 is substantially perpendicular to the longitudinal axis A2.

The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1, 2A-1 and 2A-2, nanostructure stacks 120 are formed over the fins 114A and 114B respectively, in accordance with some embodiments. Each nanostructure stack 120 includes sacrificial nanostructures 121, 123, and 125 and channel nanostructures 122, 124, and 126, in accordance with some embodiments.

The sacrificial nanostructures 121, 123, and 125 and the channel nanostructures 122, 124, and 126 are alternately and sequentially stacked over the fins 114A and 114B, in accordance with some embodiments. The sacrificial nanostructures 121, 123, and 125 and the channel nanostructures 122, 124, and 126 include nanowires or nanosheets, in accordance with some embodiments.

The sacrificial nanostructures 121, 123, and 125 are all made of the same first material, in accordance with some embodiments. The first material is different from the material of the substrate 110, in accordance with some embodiments. The first material includes an elementary semiconductor material including silicon or germanium in a single crystal structure, a polycrystal structure, or an amorphous structure, in accordance with some embodiments.

The first material includes a compound semiconductor, such as silicon carbide, gallium arsenide, gallium phosphide, indium phosphide, indium arsenide, an alloy semiconductor, such as SiGe or GaAsP, or a combination thereof, in accordance with some embodiments.

The channel nanostructures 122, 124, and 126 are all made of the same second material, in accordance with some embodiments. The second material is different from the first material, in accordance with some embodiments. The second material is the same as the material of the substrate 110, in accordance with some embodiments. The second material includes an elementary semiconductor material including silicon or germanium in a single crystal structure, a polycrystal structure, or an amorphous structure, in accordance with some embodiments.

The second material includes a compound semiconductor, an alloy semiconductor, or a combination thereof, in accordance with some embodiments. The compound semiconductor includes silicon carbide, gallium arsenide, gallium phosphide, indium phosphide, indium arsenide, a combination thereof, or another suitable compound semiconductor material, in accordance with some embodiments. The alloy semiconductor includes SiGe, SiGeSn, SiGeC, SiSn, GaAsP, GeSn, a combination thereof, or another suitable alloy semiconductor material, in accordance with some embodiments.

As shown in Figs. FIGS. 1, 2A-2 and 2A-3, an isolation layer 130 is formed over the base 112, in accordance with some embodiments. The fins 114A and 114B are partially embedded in the isolation layer 130, in accordance with some embodiments. The fins 114A and 114B are surrounded by the isolation layer 130, in accordance with some embodiments.

The isolation layer 130 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (BSG), phosphoric silicate glass (PSG), borophosphosilicate glass (BPSG), fluorinated silicate glass (FSG), or a combination thereof, in accordance with some embodiments.

The isolation layer 130 is formed using a deposition process (or a spin-on process), a chemical mechanical polishing process, and an etching back process, in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

As shown in FIGS. 1, 2A-1, 2A-2, 2A-3 and 2A-4, gate stacks 140A and 140B are formed over the nanostructure stacks 120 respectively, gate stacks 140C are formed over the isolation layer 130, and a mask layer 150 is formed over the gate stacks 140A, 140B, and 140C, in accordance with some embodiments.

Specifically, as shown in FIGS. 1, 2A-1 and 2A-3,the gate stack 140A is formed over the nanostructure stack 120, the fin 114A, and the isolation layer 130, in accordance with some embodiments. The gate stack 140A is wrapped around the nanostructure stack 120 and a top portion of the fin 114A, in accordance with some embodiments.

As shown in FIGS. 1, 2A-2 and 2A-4, the gate stacks 140B are formed over the nanostructure stack 120 and the fin 114B, in accordance with some embodiments. The gate stacks 140B are spaced apart from the isolation layer 130, in accordance with some embodiments. The longitudinal axis A3 of the gate stacks 140B and 140C is substantially parallel to the longitudinal axis A2 of the fin 114B, in accordance with some embodiments.

Each of the gate stack 140A, 140B, or 140C includes a gate dielectric layer 142 and a gate electrode 144, in accordance with some embodiments. The gate electrode 144 is over the gate dielectric layer 142, in accordance with some embodiments.

The gate dielectric layer 142 is positioned between the gate electrode 144 and the nanostructure stack 120, in accordance with some embodiments. The gate dielectric layer 142 is also positioned between the gate electrode 144 and the fin 114A, in accordance with some embodiments. The gate dielectric layer 142 is positioned between the gate electrode 144 and the isolation layer 130, in accordance with some embodiments.

The gate dielectric layer 142 is made of an oxide-containing material such as silicon oxide, in accordance with some embodiments. The gate dielectric layer 142 is formed using a chemical vapor deposition process and an etching process, in accordance with some embodiments.

The mask layer 150 is positioned over the gate stacks 140A, 140B, and 140C, in accordance with some embodiments. The mask layer 150 is made of a different material than the gate stacks 140A, 140B, and 140C, in accordance with some embodiments. The mask layer 150 is made of a different material than the gate dielectric layers 142 of the gate stacks 140A, 140B, and 140C, in accordance with some embodiments. The mask layer 150 is made of nitrides (e.g., silicon nitride) or oxynitride (e.g., silicon oxynitride), in accordance with some embodiments.

As shown in FIG. 2A-3, a gate spacer 160 is formed over sidewalls 142a of the gate dielectric layer 142, sidewalls 144a of the gate electrode 144 and sidewalls 152 of the mask layer 150, in accordance with some embodiments.

As shown in FIGS. 1, 2A-1, 2A-2, 2A-3 and 2A-4, the gate spacer 160 surrounds the gate stacks 140A, 140B, and 140C and the mask layer 150, in accordance with some embodiments. The gate spacer 160 is positioned over the nanostructure stacks 120, the fins 114A and 114B and the isolation layer 130, in accordance with some embodiments.

The gate spacer 160 includes layers 162 and 164, in accordance with some embodiments. The layer 162 conformally covers the sidewalls 142a of the gate dielectric layer 142, the sidewalls 144a of the gate electrode 144, the sidewalls 150 of the mask layer 150 and a top surface 132 of the isolation layer 130, in accordance with some embodiments. The layer 164 is formed over the layer 162, in accordance with some embodiments.

The layers 162 and 164 are made of different materials, in accordance with some embodiments. The layer 162 includes insulating materials, such as silicon oxide, silicon nitride, silicon oxynitride, or silicon carbide, in accordance with some embodiments. The layer 164 includes insulating materials, such as silicon oxide, silicon nitride, silicon oxynitride, or silicon carbide, in accordance with some embodiments.

The gate spacer 160 is made of a material different from that of the gate dielectric layers 142 of the gate stacks 140A, 140B, and 140C and the mask layer 150, in accordance with some embodiments. The formation of the gate spacer 160 includes deposition processes and an anisotropic etching process, in accordance with some embodiments.

As shown in FIGS. 2B-1 and 2B-2, portions of the sacrificial nanostructures 121, 123, and 125 and the channel nanostructures 122, 124, and 126, which are not covered by the gate stacks 140A and 140B and the gate spacer 160, are removed, in accordance with some embodiments. The removal process forms trenches TR1 in the nanostructure stack 120 over the fin 114A, in accordance with some embodiments. The trenches TR1 extend into the fin 114A, in accordance with some embodiments.

The removal process forms a trench TR2 in the nanostructure stack 120 over the fin 114B, in accordance with some embodiments. The trench TR2 extends into the fin 114B, in accordance with some embodiments.

As shown in FIGS. 2B-1 and 2B-2, sidewalls of the sacrificial nanostructures 121, 123, and 125 and the channel nanostructures 122, 124, and 126 are substantially aligned with (or substantially coplanar with) sidewalls of the gate spacer 160 over the nanostructure stack 120, in accordance with some embodiments.

The removal process removes portions of the isolation layer 130, which are not covered by the gate stacks 140A, 140B, and 140C, and therefore trenches TR3 are formed in the isolation layer 130, in accordance with some embodiments. The trench TR3 is between the gate stacks 140B and 140C, in accordance with some embodiments.

The removal process includes an etching process, in accordance with some embodiments. The etching process includes an anisotropic etching process such as a dry etching process, in accordance with some embodiments.

As shown in FIGS. 2C-1 and 2C-2, the sacrificial nanostructures 121, 123, and 125 are removed through the trenches TR1 and TR2, in accordance with some embodiments. In some embodiments, gaps GA1 are formed between the fin 114A or 114B and the channel nanostructures 122, 124, and 126 after the sacrificial nanostructures 121, 123, and 125 are removed, in accordance with some embodiments. The removal process includes an etching process such as a dry etching process and/or a wet etching process, in accordance with some embodiments.

As shown in FIGS. 2C-1 and 2C-2, a dielectric layer 170 is formed over the substrate 110 and therefore covers the fins 114A and 114B, the nanostructure stacks 120, and the gate stacks 140A, 140B, and 140C, in accordance with some embodiments. The dielectric layer 170 is filled into the gaps GA1, in accordance with some embodiments.

The dielectric layer 170 is made of semiconductor oxide materials (e.g., SiO₂ or SiO₂:F), metal oxide materials (e.g., Al₂O₃), nitrogen-containing materials (e.g., SiN or SiCON), and carbon-containing materials (e.g., SiCO), in accordance with some embodiments.

The dielectric layer 170 is formed using a deposition process such as an atomic layer deposition process, a chemical vapor deposition process, or a physical vapor deposition process, in accordance with some embodiments.

As shown in FIGS. 2D-1 and 2D-2, the dielectric layer 170 outside of the gaps GA1, which are between the fin 114A or 114B and the channel nanostructures 122, 124, and 126, and portions of the dielectric layer 170 in the gaps GA1 are removed, in accordance with some embodiments.

The dielectric layer 170 remaining in the gaps GA1 forms dielectric nanostructures 171, 172 and 173, in accordance with some embodiments. The dielectric nanostructure 171 is between the fin 114A or 114B and the channel nanostructure 122, in accordance with some embodiments. The dielectric nanostructure 172 is between the channel nanostructures 122 and 124, in accordance with some embodiments. The dielectric nanostructure 173 is between the channel nanostructures 124 and 126, in accordance with some embodiments.

In some embodiments, recesses r1 are formed in the nanostructure stacks 120 after the removal process is performed. The recesses r1 are adjacent to the dielectric nanostructures 171, 172 and 173, in accordance with some embodiments. The removal process includes an etching process such as a dry etching process, in accordance with some embodiments.

As shown in FIGS. 2D-1 and 2D-2, an inner spacer layer 180 is formed in the recesses r1 of the nanostructure stacks 120, in accordance with some embodiments. The inner spacer layer 180 and the dielectric nanostructures 171, 172 and 173 are made of different materials, in accordance with some embodiments.

The inner spacer layer 180 is made of an insulating material, such as an oxide-containing material (e.g., silicon oxide), a nitride-containing material (e.g., silicon nitride), an oxynitride-containing material (e.g., silicon oxynitride), a carbide-containing material (e.g., silicon carbide), a high-k material (e.g., HfO₂, ZrO₂, HfZrO₂, or Al₂O₃), or a low-k material, in accordance with some embodiments.

The term “high-k material” means a material having a dielectric constant greater than the dielectric constant of silicon dioxide, in accordance with some embodiments. The term “low-k material” means a material having a dielectric constant less than the dielectric constant of silicon dioxide, in accordance with some embodiments.

In some embodiments, the inner spacer layer 180 is formed using a deposition process and an etching process. The deposition process includes a physical vapor deposition process, a chemical vapor deposition process, an atomic layer deposition process, or the like, in accordance with some embodiments. In some other embodiments, the inner spacer layer 180 is formed using a selective deposition process such as an atomic layer deposition process.

As shown in FIGS. 2E-1 and 2E-2, an isolation layer 190 is formed over the fin 114A exposed by the trenches TR1 and the fin 114B exposed by the trench TR2, in accordance with some embodiments. The isolation layer 190 is made of an insulating material, such as an oxide material (e.g., silicon oxide) or a nitride material (e.g., silicon nitride), or an undoped semiconductor material (e.g., undoped silicon), in accordance with some embodiments.

The isolation layer 190 is used to electrically insulate the fin 114A or 114B from source/drain structures subsequently formed over the isolation layer 190, in accordance with some embodiments.

The formation of the isolation layer 190 includes depositing an isolation material layer over the gate stacks 140A, 140B, and 140C and in the trenches TR1, TR2 and TR3; removing the isolation material layer over the gate stacks 140A, 140B, and 140C and in the trenches TR3 using a photolithography process and an etching process; removing the isolation material layer over the inner walls of the trenches TR1 and TR2 using an etching process, wherein the remaining isolation material layer forms the isolation layer 190, in accordance with some embodiments.

In some other embodiments, the formation of the isolation layer 190 includes performing an epitaxial process.

As shown in FIG. 2E-1, source/drain structures 210 are formed in the trenches TR1 and TR2, in accordance with some embodiments. The channel nanostructures 122, 124, and 126 and the dielectric nanostructures 171, 172 and 173 are between the source/drain structures 210, in accordance with some embodiments. The source/drain structures 210 are in direct contact with the channel nanostructures 122, 124, and 126, the gate spacer 160, and the inner spacer layer 180, in accordance with some embodiments.

The source/drain structure 210 has lightly doped portions 212 and a heavily doped portion 214, in accordance with some embodiments. The dopant concentration of the lightly doped portions 212 is less than that of the heavily doped portion 214, in accordance with some embodiments. The lightly doped portions 212 are connected to the channel nanostructures 122, 124, and 126, in accordance with some embodiments. The lightly doped portions 212 are embedded in the heavily doped portion 214, in accordance with some embodiments.

The source/drain structures 210 are made of a semiconductor material (e.g., silicon germanium) with P-type dopants, such as the Group IIIA element, in accordance with some embodiments. The Group IIIA element includes boron or another suitable material.

In some other embodiments, the source/drain structures 210 are made of a semiconductor material (e.g., silicon) with N-type dopants, such as the Group VA element, in accordance with some embodiments. The Group VA element includes phosphor (P), antimony (Sb), or another suitable Group VA material. The source/drain structures 210 are formed using an epitaxial process, in accordance with some embodiments.

As shown in FIGS. 2E-1 and 2E-2, a dielectric structure 220 is formed over the source/drain structures 210, in accordance with some embodiments. The dielectric structure 220 includes an etch stop layer 222 and a dielectric layer 224, in accordance with some embodiments. The etch stop layer 222 conformally coves the source/drain structures 210 and the gate spacer 160, in accordance with some embodiments. The dielectric layer 224 is formed over the etch stop layer 222, in accordance with some embodiments.

The etch stop layer 222 and the dielectric layer 224 are made of different materials, in accordance with some embodiments. The etch stop layer 222 includes a dielectric material such as a nitride-containing material (e.g., silicon nitride), an oxynitride-containing material (e.g., silicon oxynitride), or a combination thereof, in accordance with some embodiments.

The dielectric layer 224 includes a dielectric material such as an oxide-containing material (e.g., silicon oxide), an oxynitride-containing material (e.g., silicon oxynitride), a low-k material, a porous dielectric material, glass, or a combination thereof, in accordance with some embodiments.

The glass includes borosilicate glass (BSG), phosphoric silicate glass (PSG), borophosphosilicate glass (BPSG), fluorinated silicate glass (FSG), or a combination thereof, in accordance with some embodiments. The dielectric layer 224 is formed by a deposition process (e.g., a chemical vapor deposition process) and a planarization process (e.g., a chemical mechanical polishing process), in accordance with some embodiments.

As shown in FIGS. 2E-1 and 2E-2, a ceiling layer 230 is formed over the dielectric structure 220, in accordance with some embodiments. The etch resistance of the ceiling layer 230 is greater than that of the dielectric structure 220, in accordance with some embodiments. The ceiling layer 230 is made of an etching resisting material such as a nitride material (e.g., silicon nitride), in accordance with some embodiments.

FIG. 2F-3 is a top view of the semiconductor device structure of FIGS. 2F-1 and 2F-2, in accordance with some embodiments. FIG. 2F-1 is a cross-sectional view illustrating the semiconductor device structure along a sectional line I-I’ in FIG. 2F-3, in accordance with some embodiments. FIG. 2F-2 is a cross-sectional view illustrating the semiconductor device structure along a sectional line II-II’ in FIG. 2F-3, in accordance with some embodiments.

As shown in FIGS. 2F-1, 2F-2 and 2F-3, a mask layer 240 is formed over the substrate 110 to cover the ceiling layer 230, the mask layer 150, and the gate spacer 160, in accordance with some embodiments. The mask layer 240 has an opening 242, in accordance with some embodiments. The opening 242 exposes the mask layer 150 over the right one of the gate stacks 140A and the gate spacer 160, in accordance with some embodiments. The mask layer 240 is made of an etching resisting material such as a nitride material (e.g., silicon nitride), in accordance with some embodiments.

FIG. 2G-3 is a top view of the semiconductor device structure of FIGS. 2G-1 and 2G-2, in accordance with some embodiments. FIG. 2G-1 is a cross-sectional view illustrating the semiconductor device structure along a sectional line I-I’ in FIG. 2G-3, in accordance with some embodiments.

FIG. 2G-2 is a cross-sectional view illustrating the semiconductor device structure along a sectional line II-II’ in FIG. 2G-3, in accordance with some embodiments. FIG. 2G-4 is a cross-sectional view illustrating the semiconductor device structure along a sectional line III-III’ in FIG. 2G-3, in accordance with some embodiments.

As shown in FIGS. 2G-1, 2G-2, 2G-3 and 2G-4 the mask layer 150, the gate stack 140A, the channel nanostructures 122, 124, and 126, and the dielectric nanostructures 171, 172 and 173 are partially removed to form a trench TR4 passing through the gate stack 140A, the channel nanostructures 122, 124, and 126, and the dielectric nanostructures 171, 172 and 173, in accordance with some embodiments. As shown in FIG. 2G-3, the gate stack 140A is divided into portions 140A1 and 140A2 by the trench TR4, in accordance with some embodiments.

The removal process may further remove a portion of the substrate 110 under the removed dielectric nanostructure 171. Therefore, the trench TR4 extends into the fin 114A, in accordance with some embodiments. In some embodiments, the trench TR4 passes through the fin 114A. In some embodiments, the trench TR4 further extends into the base 112.

In the trench TR4, the inner walls 154, S140A1, and 134 of the mask layer 150, the portion 140A1 of the gate stack 140A, and the isolation layer 130 are substantially level with each other, and the inner walls 156, S140A2, and 136 of the mask layer 150, the portion 140A2 of the gate stack 140A, and the isolation layer 130 are substantially level with each other, in accordance with some embodiments.

As illustrated in FIG. 2G-1, the removal process may further remove an upper portion of the gate spacer 160. Therefore, a width W1 of the trench TR4 increases toward the top surface 160a of the gate spacer 160, in accordance with some embodiments. In some embodiments, the width W1 may narrow through the channel nanostructures 122, 124, and 126. The width W1 may increase below the channel nanostructures 122, 124, and 126 and then taper as the trench TR4 extends into the fin 114A. The removal process includes an etching process such as a dry etching process, in accordance with some embodiments.

As shown in FIGS. 2H-1 and 2H-2, a liner layer 252 is formed over the mask layer 240 and in the trench TR4, in accordance with some embodiments. The liner layer 252 conformally covers the inner walls TR4a and the bottom surface TR4b of the trench TR4, in accordance with some embodiments.

The liner layer 252 is made of an insulating material such as an oxide material (e.g., SiO₂, SiCO, or SiO₂:F) in accordance with some embodiments. The liner layer 252 is formed using a deposition process such as an atomic layer deposition process, in accordance with some embodiments. In some embodiments, the liner layer 252 is formed using a deposition process such as a chemical vapor deposition process or a physical vapor deposition process.

As shown in FIGS. 2H-1 and 2H-2, an etch resist layer 254 is formed over the liner layer 252, in accordance with some embodiments. The etch resist layer 254 has an air gap AG, in accordance with some embodiments. In some embodiments, air is in the air gap AG. The etch resist layer 254 is made of a dielectric material with good etch resistance such as a nitride material (e.g., SiN, SiCN, or SiCON), in accordance with some embodiments.

In some embodiments, the etch resist layer 254 is made of oxide materials or carbon-containing materials (e.g., SiCO), in accordance with some embodiments. The oxide materials include semiconductor oxide materials (e.g., SiO₂ or SiO₂:F) or metal oxide materials (e.g., Al₂O₃), in accordance with some embodiments.

The etch resist layer 254 is formed using a deposition process such as an atomic layer deposition process, in accordance with some embodiments. In some other embodiments, the etch resist layer 254 is formed using a deposition process such as a chemical vapor deposition process or a physical vapor deposition process.

As shown in FIGS. 2H-1 and 2H-2, a planarization layer 256 is formed over the etch resist layer 254, in accordance with some embodiments. The planarization layer 256 is made of a dielectric material such as a nitride material (e.g., silicon nitride), in accordance with some embodiments.

The planarization layer 256 is formed using a deposition process such as a chemical vapor deposition process (e.g., plasma-enhanced chemical vapor deposition), in accordance with some embodiments. In some other embodiments, the planarization layer 256 is formed using a deposition process such as a physical vapor deposition process.

As shown in FIGS. 2H-1 and 2H-2, a planarization layer 258 is formed over the planarization layer 256, in accordance with some embodiments. The planarization layer 258 is made of a dielectric material such as an oxide material (e.g., silicon oxide), in accordance with some embodiments.

The planarization layer 258 is formed using a deposition process such as a chemical vapor deposition process (e.g., plasma-enhanced chemical vapor deposition), in accordance with some embodiments. In some other embodiments, the planarization layer 258 is formed using a deposition process such as a physical vapor deposition process.

FIG. 2I-3 is a top view of the semiconductor device structure of FIGS. 2I-1 and 2I-2, in accordance with some embodiments. FIG. 2I-1 is a cross-sectional view illustrating the semiconductor device structure along a sectional line I-I’ in FIG. 2I-3, in accordance with some embodiments. FIG. 2I-2 is a cross-sectional view illustrating the semiconductor device structure along a sectional line II-II’ in FIG. 2I-3, in accordance with some embodiments.

As shown in FIGS. 2H-1, 2I-1, 2I-2 and 2I-3, portions of the liner layer 252 and the etch resist layer 254 outside of the trench TR4, the planarization layer 256 and 258, the mask layer 240, the ceiling layer 230, the mask layer 150, and upper portions of the gate stacks 140A, 140B, and 140C, the gate spacer 160, and the dielectric structure 220 are removed, in accordance with some embodiments.

The liner layer 252 and the etch resist layer 254 remaining in the trench TR4 together form a gate cut structure 250, in accordance with some embodiments. The gate cut structure 250 passes through the gate spacer 160, the gate stack 140A, the channel nanostructures 122, 124, and 126, and the dielectric nanostructures 171, 172 and 173, in accordance with some embodiments.

The gate cut structure 250 extends into the substrate 110, in accordance with some embodiments. The gate cut structure 250 extends into the fin 114A, in accordance with some embodiments. In some embodiments, the gate cut structure 250 passes through the fin 114A. In some embodiments, the gate cut structure 250 further extends into the base 112.

The dielectric nanostructure 171 is between the inner spacer 180 and the gate cut structure 250, in accordance with some embodiments. The dielectric nanostructure 172 is between the inner spacer 180 and the gate cut structure 250, in accordance with some embodiments. The dielectric nanostructure 173 is between the inner spacer 180 and the gate cut structure 250, in accordance with some embodiments.

The inner spacer 180 is between the source/drain structures 210 and the dielectric nanostructures 172 and 173, in accordance with some embodiments. The inner spacer 180 is between the isolation layer 190 and the dielectric nanostructure 171, in accordance with some embodiments.

In some embodiments, a width W250 of the gate cut structure 250 decreases from the top surface 160a of the gate spacer 160 toward the channel nanostructures 122, 124, and 126. The gate cut structure 250 has a portion 251 in the fin 114A, in accordance with some embodiments.

The portion 251 has an upper part 251a and a lower part 251b, in accordance with some embodiments. In some embodiments, a width W251a of the upper part 251a decreases toward the dielectric nanostructures 171, 172 and 173. In some embodiments, a width W251b of the lower part 251b decreases toward the base 112.

The dielectric nanostructures 171, 172 and 173 are in contact with the gate cut structure 250 and the inner spacer 180, in accordance with some embodiments. The dielectric nanostructure 171 is in contact with the channel nanostructure 122, in accordance with some embodiments. The dielectric nanostructure 172 is in contact with the channel nanostructures 122 and 124, in accordance with some embodiments.

The dielectric nanostructure 173 is in contact with the channel nanostructures 124 and 126, in accordance with some embodiments. The gate cut structure 250 are between the source/drain structures 210, which are electrically isolated from each other by the gate cut structure 250, in accordance with some embodiments. The removal process includes a planarization process such as a chemical mechanical polishing process, in accordance with some embodiments.

FIG. 2J-3 is a top view of the semiconductor device structure of FIGS. 2J-1 and 2J-2, in accordance with some embodiments. FIG. 2J-1 is a cross-sectional view illustrating the semiconductor device structure along a sectional line I-I’ in FIG. 2J-3, in accordance with some embodiments.

FIG. 2J-2 is a cross-sectional view illustrating the semiconductor device structure along a sectional line II-II’ in FIG. 2J-3, in accordance with some embodiments. FIG. 2J-4 is a cross-sectional view illustrating the semiconductor device structure along a sectional line IV-IV’ in FIG. 2J-3, in accordance with some embodiments.

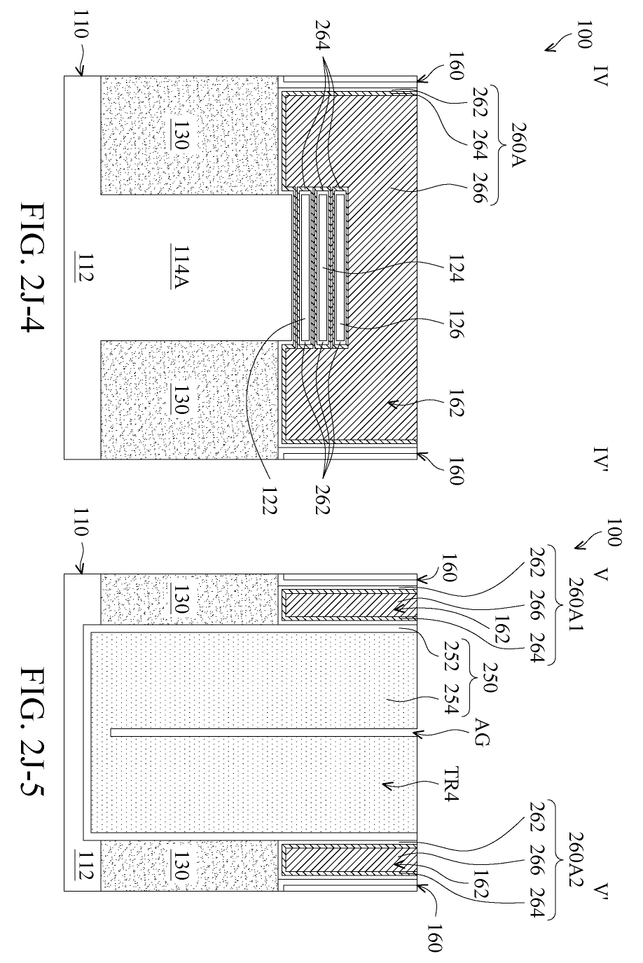

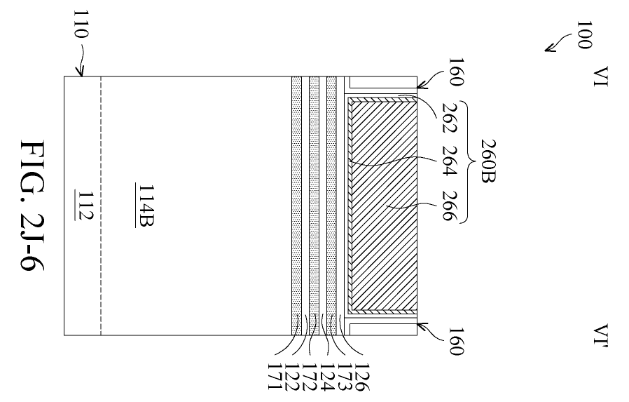

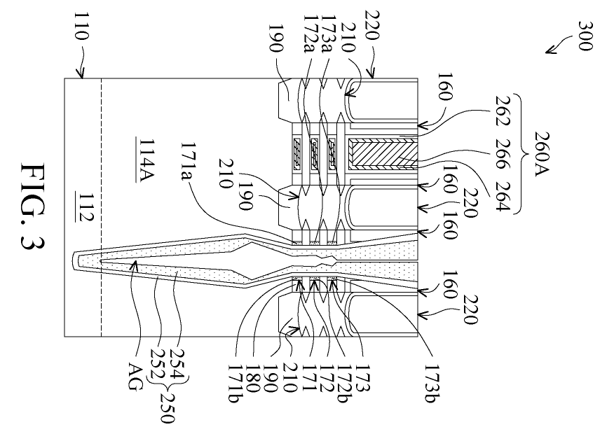

FIG. 2J-5 is a cross-sectional view illustrating the semiconductor device structure along a sectional line V-V’ in FIG. 2J-3, in accordance with some embodiments. FIG. 2J-6 is a cross-sectional view illustrating the semiconductor device structure along a sectional line VI-VI’ in FIG. 2J-3, in accordance with some embodiments.

As shown in FIGS. 2J-1, 2J-2, 2J-3, 2J-4, 2J-5 and 2J-6, the gate stacks 140A, 140B, and 140C are removed, in accordance with some embodiments. The removal process forms trenches 162 in the gate spacer 160, in accordance with some embodiments.

As shown in FIGS. 2J-1 and 2J-4, the dielectric nanostructures 171, 172, and 173 are removed through the trenches 162, in accordance with some embodiments. The removal process for removing the gate stacks 140A, 140B, and 140C and the dielectric nanostructures 171, 172, and 173 includes an etching process such as a wet etching process or a dry etching process, in accordance with some embodiments.

As shown in FIGS. 2J-1, 2J-2, 2J-3, 2J-4, 2J-5 and 2J-6, gate stacks 260A, 260A1, and 260A2 and sealing gate stacks 260B and 260C are formed in the trenches 162, in accordance with some embodiments. In this step, a semiconductor device structure 100 is substantially formed, in accordance with some embodiments.

As shown in FIG. 2J-4, the gate stack 260A surrounds the channel nanostructures 122, 124, and 126, in accordance with some embodiments. As shown in FIGS. 2J-2 and 2J-3, the sealing gate stacks 260B are over the channel nanostructures 122, 124, and 126, in accordance with some embodiments. In some embodiments, a longitudinal axis A3 of the sealing gate stacks 260B is substantially parallel to the longitudinal axis A2 of the fin 114B.

The longitudinal axis A1 of the fin 114A is not parallel to the longitudinal axis A3 of the sealing gate stacks 260B, in accordance with some embodiments. In some embodiments, the longitudinal axis A1 is substantially perpendicular to the longitudinal axis A3. As shown in FIGS. 2J-2 and 2J-3, the sealing gate stacks 260C are over the isolation layer 130, in accordance with some embodiments.

The sealing gate stacks 260B and 260C and the fin 114B together form a seal ring structure 270, in accordance with some embodiments. The seal ring structure 270 is used to protect the devices in the device region 110D from being attacked by moisture, in accordance with some embodiments.

As shown in FIG. 2J-2, a sidewall S260B of the sealing gate stack 260B is connected to a sidewall S126 of the channel nanostructure 126, in accordance with some embodiments. The sidewall S126 of the channel nanostructure 126 is connected between the sidewall S260B of the sealing gate stack 260B and a sidewall S173 of the dielectric nanostructure 173, in accordance with some embodiments.

In some embodiments, a sidewall S171 of the dielectric nanostructure 171 is connected to a sidewall S114B of the fin 114B. The channel nanostructures 122, 124, and 126 are between the gate stack 260B and the dielectric nanostructure 171, in accordance with some embodiments.

As shown in FIG. 2J-1, the dielectric nanostructures 172 and 173 are between the gate cut structure 250 and the source/drain structure 210, in accordance with some embodiments. The dielectric nanostructure 171 is between the gate cut structure 250 and the isolation layer 190, in accordance with some embodiments.

Each of the gate stack 260A, 260B, or 260C includes a gate dielectric layer 262, a work function metal layer 264, and a gate electrode layer 266, in accordance with some embodiments. The gate dielectric layer 262 conformally covers the channel nanostructures 122, 124, and 126 in FIG. 2J-1 and inner walls and bottom surfaces of the trenches 162, in accordance with some embodiments.

The gate dielectric layer 262 is made of a high-K material, such as HfO₂, ZrO₂, HfZrO₂, or Al₂O₃, in accordance with some embodiments. The gate dielectric layer 262 is formed using an atomic layer deposition process or another suitable process.

The work function metal layer 264 is conformally formed over the gate dielectric layer 262, in accordance with some embodiments. The work function metal layer 264 is made of titanium-containing material (e.g., TiN or TiSiN) or tantalum-containing material (e.g., TaN), or another suitable conductive material. The work function metal layer 264 is formed using an atomic layer deposition process or another suitable process.

The gate electrode layer 266 is formed over the work function metal layer 264, in accordance with some embodiments. The gate electrode layer 266 is made of W, Co, Al, or another suitable conductive material. The gate electrode layer 266 is formed using an atomic layer deposition process or another suitable process.

Since the sacrificial nanostructures 121, 123, and 125, for example made of SiGe, are replaced by the dielectric nanostructures 171, 172 and 173 before the source/drain structures 210 are formed, Ge atoms in the sacrificial nanostructures 121, 123, and 125 are prevented from diffusing into the channel nanostructures 122, 124, and 126 during the formation of the source/drain structures 210, which improves the planarity of the channel surfaces of the channel nanostructures 122, 124, and 126, in accordance with some embodiments. Therefore, the channel resistance is reduced and the mobility of the channel nanostructures 122, 124, and 126 is improved, which improves the performance of the semiconductor device structure 100, in accordance with some embodiments.

FIG. 3 is a cross-sectional view illustrating a semiconductor device structure 300, in accordance with some embodiments. As shown in FIG. 3, the semiconductor device structure 300 is similar to the semiconductor device structure 100, except that the dielectric nanostructure 171 has portions 171a and 171b, the dielectric nanostructure 172 has portions 172a and 172b, and the dielectric nanostructure 173 has portions 173a and 173b, in accordance with some embodiments.

The gate cut structure 250 is between the portions 171a and 171b, in accordance with some embodiments. The gate cut structure 250 is between the portions 172a and 172b, in accordance with some embodiments. The gate cut structure 250 is between the portions 173a and 173b, in accordance with some embodiments.

Processes and materials for forming the semiconductor device structure 300 may be similar to, or the same as, those for forming the semiconductor device structure 100 described above. Elements designated by the same or similar reference numbers as those in FIGS. 1 to 3 have the same or similar structures and the materials. Therefore, the detailed descriptions thereof will not be repeated herein.

In accordance with some embodiments, semiconductor device structures and methods for forming the same are provided. The methods (for forming the semiconductor device structure) replace sacrificial nanostructures, for example made of SiGe, with dielectric nanostructures before source/drain structures are formed, Ge atoms in the sacrificial nanostructures are prevented from diffusing into channel nanostructures during the formation of the source/drain structures, which improves the planarity of the channel surfaces of the channel nanostructures. Therefore, the channel resistance is reduced and the mobility of the channel nanostructures is improved, which improves the performance of the semiconductor device structure.

In accordance with some embodiments, a semiconductor device structure is provided. The semiconductor device structure includes a substrate. The semiconductor device structure includes a channel nanostructure and a dielectric nanostructure over the substrate. The dielectric nanostructure is between the substrate and the channel nanostructure. The semiconductor device structure includes a gate cut structure passing through the channel nanostructure and the dielectric nanostructure. The semiconductor device structure includes an inner spacer between the channel nanostructure and the substrate. The dielectric nanostructure is between the inner spacer and the gate cut structure. The semiconductor device structure includes a first source/drain structure over the substrate and connected to the channel nanostructure. The inner spacer is between the first source/drain structure and the dielectric nanostructure.

In accordance with some embodiments, a semiconductor device structure is provided. The semiconductor device structure includes a substrate includes a base and a fin over the base. The semiconductor device structure includes a channel nanostructure and a dielectric nanostructure over the fin. The dielectric nanostructure is between the fin and the channel nanostructure. The semiconductor device structure includes a sealing gate stack over the channel nanostructure, wherein a first longitudinal axis of the sealing gate stack is substantially parallel to a second longitudinal axis of the fin.

In accordance with some embodiments, a method for forming a semiconductor device structure is provided. The method includes providing a substrate, a first sacrificial nanostructure, a first channel nanostructure, and a first gate stack. The first sacrificial nanostructure is between the substrate and the first channel nanostructure, and the first gate stack is wrapped around the first sacrificial nanostructure and the first channel nanostructure. The method includes removing the first sacrificial nanostructure to form a first gap between the substrate and the first channel nanostructure. The method includes forming a first dielectric nanostructure in the first gap. The method includes forming a first source/drain structure over the substrate and connected to the first channel nanostructure. The method includes partially removing the first gate stack, the first channel nanostructure, and the first dielectric nanostructure to form a trench passing through the first gate stack, the first channel nanostructure, and the first dielectric nanostructure. The method includes forming a gate cut structure in the trench, wherein a portion of the first dielectric nanostructure is between the gate cut structure and the first source/drain structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a nanostructure stack over a substrate, the nanostructure stack comprising a sacrificial nanostructure between the substrate and a channel nanostructure;
forming a gate stack wrapped around the nanostructure stack;
replacing the sacrificial nanostructure with a dielectric nanostructure;
forming a source/drain structure connected to the channel nanostructure; and
forming a gate cut structure passing through the gate stack, the channel nanostructure, and the dielectric nanostructure, wherein the gate cut structure divides the gate stack into a first portion and a second portion and divides the dielectric nanostructure into a first dielectric portion and a second dielectric portion.

2. The method of claim 1, wherein replacing the sacrificial nanostructure with the dielectric nanostructure comprises:
removing the sacrificial nanostructure to form a gap between the substrate and the channel nanostructure;
forming a dielectric layer filling the gap; and
removing a portion of the dielectric layer to form the dielectric nanostructure.

3. The method of claim 2, further comprising:
forming an inner spacer adjacent the dielectric nanostructure.

4. The method of claim 3, wherein the inner spacer and the dielectric nanostructure comprise different materials.

5. The method of claim 1, wherein forming the gate cut structure comprises:
forming a trench through the gate stack, the channel nanostructure, and the dielectric nanostructure;
forming a liner layer conformally covering an inner wall and a bottom surface of the trench; and
forming an dielectric layer over the liner layer.

6. The method of claim 5, wherein the etch resist layer has an air gap.

7. The method of claim 1, wherein the gate cut structure extends into the substrate.

8. The method of claim 1, wherein a width of the gate cut structure decreases from a top of the gate cut structure toward the channel nanostructure.

9. A method for forming a semiconductor device, comprising:
forming a nanostructure stack over a fin of a substrate, the nanostructure stack comprising a channel nanostructure and a sacrificial nanostructure between the fin and the channel nanostructure;
replacing the sacrificial nanostructure with a dielectric nanostructure;
forming a source/drain structure connected to the channel nanostructure; and
forming a gate cut structure passing through the channel nanostructure and the dielectric nanostructure and extending into the fin, wherein the gate cut structure has a portion in the fin, wherein the portion has an upper part having a width decreasing toward the dielectric nanostructure and a lower part having a width decreasing toward a base of the substrate, wherein a remaining portion of the dielectric nanostructure is between the gate cut structure and the source/drain structure.

10. The method of claim 9, wherein the gate cut structure has an air gap.

11. The method of claim 9, wherein the gate cut structure passes through the fin and extends into the base of the substrate.

12. The method of claim 9, wherein a width of the gate cut structure decreases from a top of the gate cut structure toward the channel nanostructure.

13. The method of claim 9, further comprising:
forming an inner spacer, wherein the inner spacer is between the source/drain structure and the dielectric nanostructure.

14. The method of claim 9, wherein the dielectric nanostructure is in contact with the channel nanostructure and the gate cut structure.

15. A semiconductor device, comprising:
a substrate;
a semiconductor nanostructure over the substrate;
a dielectric nanostructure between the substrate and the semiconductor nanostructure, wherein the dielectric nanostructure is in contact with the semiconductor nanostructure;
an inner spacer between the substrate and the semiconductor nanostructure, wherein the inner spacer is in contact with the dielectric nanostructure; and
a gate cut structure in contact with the dielectric nanostructure, wherein the dielectric nanostructure is between the gate cut structure and the inner spacer.

16. The semiconductor device of claim 15, wherein the gate cut structure extends into the substrate.

17. The semiconductor device of claim 15, wherein the substrate comprises a base and a fin over the base, and wherein the gate cut structure extends into the fin.

18. The semiconductor device of claim 17, wherein the gate cut structure passes through the fin and extends into the base.

19. The semiconductor device of claim 17, wherein the gate cut structure has a portion in the fin, wherein the portion has an upper part having a width decreasing toward the dielectric nanostructure and a lower part having a width decreasing toward the base of the substrate.

20. The semiconductor device of claim 15, wherein the gate cut structure has an air gap.
